(19) United States
(12) Patent Application Publication
(10) Pub. No.: US 2008/0092714 A1
(43) Pub. Date: Apr. 24, 2008

(54) MULTILAYER DICING BLADE

(75) Inventors: Ariel L. Miranda, Daraga (PH); Jeniffer V. Otero, Baguio City (PH); Richard M. Ainza, Santol (PH)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/539,677

(22) Filed: Oct. 9, 2006

(51) Int. Cl. B23D 51/10; H01L 21/00

(52) U.S. Cl. 83/699.21; 438/460

(57) ABSTRACT

A semiconductor dicing blade comprising a blade body, a first grit located within a core of the blade body, and a second different grit located on a side surface of the blade body wherein the first grit has a first grit size and is exposed at a lead cutting edge of the blade body, and wherein a largest grit particle of the second different grit is smaller than a smallest grit particle of the first grit. A method of cutting a semiconductor wafer is also provided.

### TECHNICAL FIELD OF THE INVENTION

The present invention is directed, in general, to semiconductor manufacturing tools and, more specifically, to a multilayer dicing blade for separating die on a semiconductor wafer.

### BACKGROUND OF THE INVENTION

During semiconductor manufacturing a plurality of die are formed on a single wafer. Once formed, the plurality of die must be separated into individual pieces for continued manufacturing of the finished product. This is usually done by sawing the wafer with a circular saw blade impregnated with very fine diamond pieces known as grit embedded in a nickel matrix. The saw blade may have a metal, usually aluminum, hub for attaching to the power saw. The saw blade necessarily destroys that part of the wafer where it cuts what is traditionally known as a kerf, or in the parlance of semiconductor manufacturing: a street or scribe street. Scribe street width is dictated by a combination of wafer properties, blade dimensions and properties, as well as table tracking speed and spindle speed. A good dicing operation is essential to the manufacturing process because the wafer has its highest value at the sawing stage. Regardless of how fine the diamond grit is, chips or peel-off of the area immediately adjacent to the kerf occurs in what is generally the scribe seal or ground ring of the die. Damage to these areas creates a reliability risk that can result in open or short circuit failures at electrical testing and rejection of the die.

One who is of skill in the art will recognize that a conventional scribe street may have a street width of 62 microns. With a blade width of 30 microns and a street width of 62 microns, there is only 16 microns clearance on either side of the blade. The semiconductor manufacturing industry is moving toward narrower scribe streets, e.g., 52 microns, in an effort to obtain higher die yields per wafer. In order to work with a street width of 52 microns, the blade must be no more than 20 microns thick to maintain the same clearance on either side of the blade as the prior art. However, reducing the saw blade thickness to enable a narrower kerf has a practical limit driven by the size of the diamond grit and the ability of the nickel matrix to hold the grit. Thinner blades also equate to fast blade wear and therefore shortened blade life. Thinner blades also increase the risk of catastrophic failure of the blade which, if it occurs during cutting, usually results in severe chipping of the die, and ultimately die rejection. Faster blade wear also means more frequent blade changes and eventually higher operating costs. Making the grit size larger or the grit concentration higher to offset fast blade wear results in larger chipping or peel-off. Therefore, the prior art blade design is not adequate for very small scribe street widths because solving one problem, e.g., fast blade wear with larger grit may create another problem, i.e., chipping and peeling.

Accordingly, what is needed in the art is a dicing blade that does not suffer from the deficiencies of the prior art.

### SUMMARY OF THE INVENTION

To address the above-discussed deficiencies of the prior art, the invention provides a semiconductor dicing blade comprising a first region having a first grit therein, and a second region coupled to the first region and having a second different grit therein.

In another embodiment, the invention provides a method of cutting a semiconductor wafer. The method comprises positioning a semiconductor dicing blade mounted in a wafer saw wherein the semiconductor dicing blade comprises a core region having a first diameter and a first grit therein and a surface region coupled to the core region and having a second diameter. The surface region has a second different grit therein, wherein a largest grit particle of the second different grit is smaller than a smallest grit particle of the first grit. The first diameter is slightly greater than the second diameter, and the first grit is larger than the second different grit. The method further includes operating the wafer saw to cut a semiconductor wafer with the semiconductor dicing blade.

In another embodiment, the invention provides a semiconductor dicing blade that comprises a blade body and a first grit located within a core of the blade body. The first grit has a first grit size that is exposed at a lead cutting edge of the blade body, and a second different grit is located on a side surface of the blade body. The second different grit has a second different grit size smaller than the first grit size.

### BRIEF DESCRIPTION OF THE DRAWINGS

For a more complete understanding of the present invention, reference is now made to the following descriptions taken in conjunction with the accompanying drawings, in which:

FIG. 1A illustrates a dicing blade constructed according to the principles of the invention;

FIG. 1B illustrates a magnified edge view of the dicing blade of FIG. 1A;

FIG. 2 illustrates the dicing blade of FIGS. 1A and 1B as the dicing blade cuts through a wafer on a tape having a thickness of about 3 mils;

FIG. 3 illustrates the dicing blade of FIG. 2 cutting through the semiconductor wafer; and

FIG. 4 illustrates a profile view of the dicing blade and a sectional view of the semiconductor wafer along the center plane of the dicing blade as it cuts.

### DETAILED DESCRIPTION

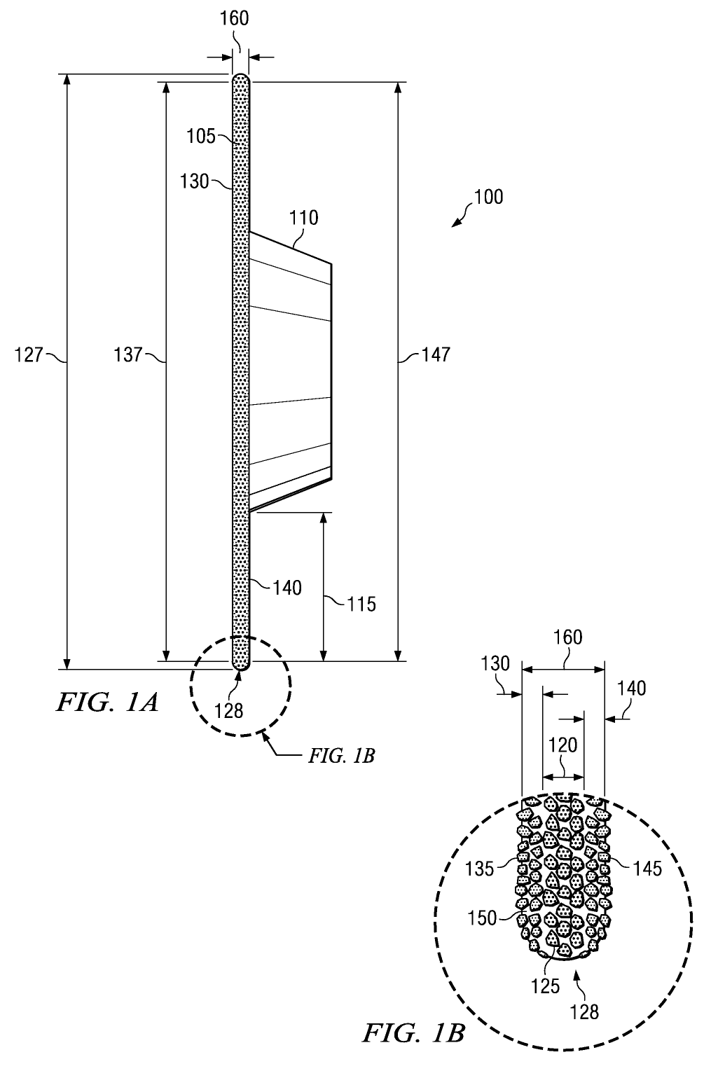

In FIG. 1A, there is a view of a dicing blade 100 constructed according to the principles of the invention. FIG. 1B shows a magnified edge view of the dicing blade of FIG. 1A with a cutting edge 105. The dicing blade 100 comprises the cutting edge 105, a hub 110, a cutting portion 115, and a core region 120. A first grit 125 is located in the core region 120. The dicing blade 100 further includes a first surface region 130, in which a second different grit 135 is located; a second surface region 140, in which a third grit 145 is located; and a matrix 150. As used herein, the term “a second different grit” means a grit wherein the largest grit particle of the second different grit is smaller than the smallest grit particle of the first grit. The third grit 145 may or may not be the same size as the second different grit 135. For clarity, the FIGS. illustrating this invention will not be to scale, but rather will exaggerate the cutting portion 115 of the dicing blade 100. In one embodiment, the hub 110 may be an aluminum hub for mounting the dicing blade 100 to a wafer cutting saw (not shown). One who is of skill in the art is familiar with the operation of wafer cutting saws.

The core 120 comprises the first grit 125, which in one embodiment may be diamond grit, bonded in the matrix 150. The matrix 150 should be comprised of a material sufficient to bond or hold the first grit 125 in place during cutting. In one embodiment, the matrix 150 may comprise a metal, such as nickel. The first grit 125 has a grit size of less than about 10 microns. For example, the first grit 125 size may range from about 4 microns to about 6 microns. However, the second different grit 135 is smaller than the first grit 125. In one embodiment, the second different grit 135 may have a grit size less than about 5 microns. For example, the second different grit size 135 may range from about 2 microns to about 4 microns. The third grit 145 may be either the same size or a different size than the second different grit 135. In one embodiment, however, the third grit 145 is the same size as the second different grit 135. It should be noted that the smaller the grit size, the finer the cut and the better the end product with fewer risks of testing failures or damage to adjacent electrical structures. While the thickness may vary, in one embodiment, a thickness 160 of the cutting portion 115 is less than about 30 microns. For example, the thickness 160 may be about 20 microns. It is important that this overall thickness be a thin as possible without sacrificing blade strength because the blade thickness 160 determines the majority of the kerf width. Furthermore, a thinner blade with standard blade exposure 115 will increase the likelihood of blade instability that can result in blade breakage. Reducing the blade exposure 115 introduces the need for more frequent blade changes resulting in more blades used and more operator time to install the blades, thereby raising cost of both materials and labor. With a blade thickness of about 20 microns designed as provided by the invention, it is now possible to achieve kerf widths compatible with scribe street widths of 52 microns or less. This may be compared to previous scribe street widths of 62 microns from blades with a 30 micron thickness. Thus, die yield per wafer is significantly enhanced.

The dicing blade 100 has a core overall diameter 127 that is a diameter of the core 120 comprising the first grit 125. The first surface region 130 has a first surface region diameter 137 that is slightly less than the core overall diameter 127. The second surface region 140 has a second surface region diameter 147 that is also slightly less than the core diameter 127. The first surface region diameter 137 and the second surface region diameter 147 are substantially equal. The relative sizes of the core diameter 127 to the first surface region diameter 137 and the second surface region diameter 147 enable a leading edge 128 of the core 120 with first grit 125 to cut the semiconductor wafer before the grit of the first and second surface regions 130, 140, respectively. Of course, one who is of skill in the art will recognize that this condition of a larger relative core diameter 127 is the ideal of a new blade. As the blade wears, many factors will affect the actual condition of the core diameter 127 versus the first and second surface region diameters 137, 147.

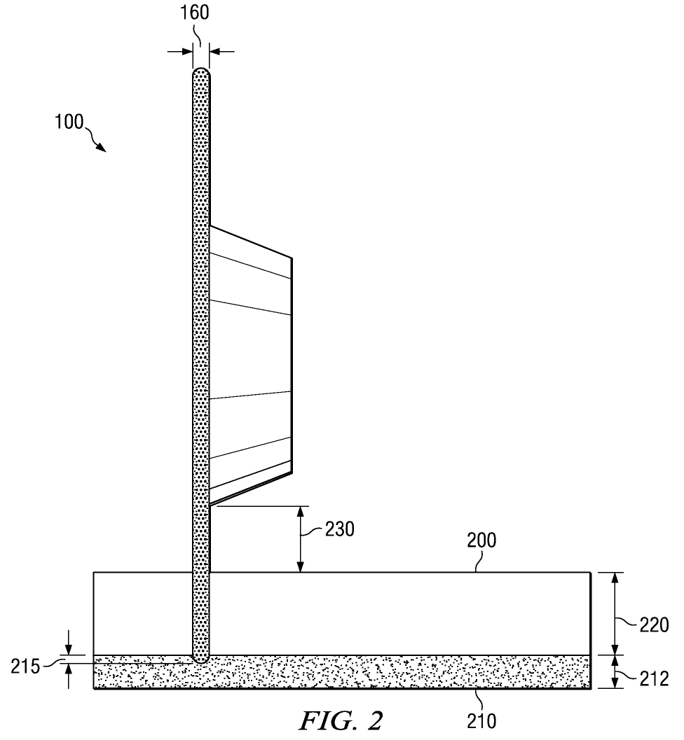

In one embodiment, the cutting portion 115 has a new blade exposure less than about 900 microns. Specifically, the new blade exposure 115 may range from about 760 microns to about 890 microns. The term “new blade exposure” 115 is used here because the blade exposure will change, i.e., be reduced by blade wear, as wafer cutting is performed; ultimately reaching a minimum useable point where the blade exposure 115 equals the cut depth plus the safety exposure. FIG. 2 illustrates an edge view of the dicing blade 100 of FIGS. 1A and 1B as the dicing blade cuts through a wafer 200 on a tape 210 having a tape thickness 212 of about 3 mils. A required cut depth is equal to a maximum die thickness 220, nominally 11 mils, plus a tape cut thickness 215 of 1 mil to assure die separation. Adding a safety exposure 230 to prevent hub damage to the die, which is usually 4 mils, to the required cut depth of 12 mils equals a minimum useable blade exposure of 16 mils.

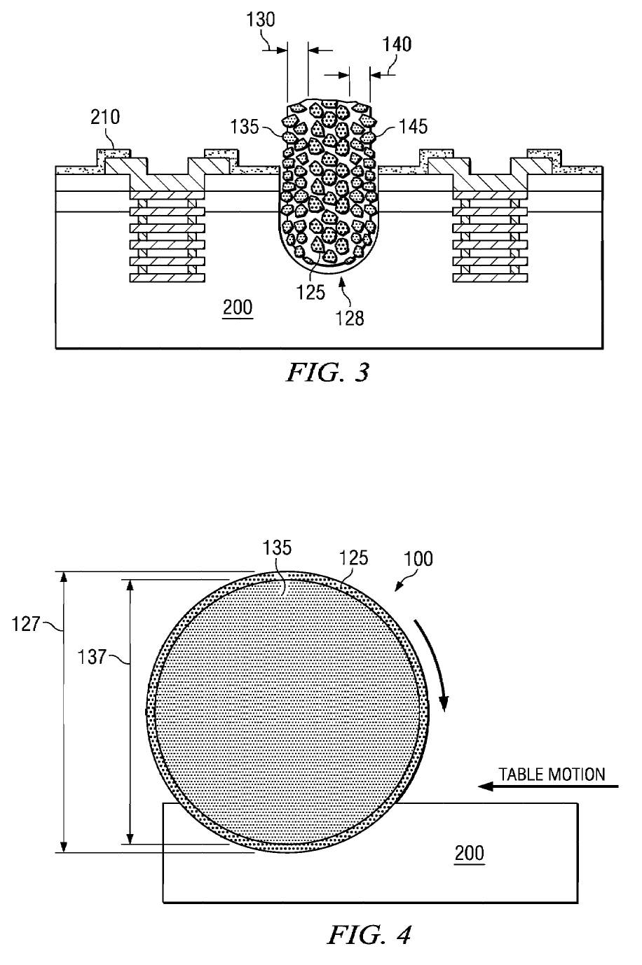

FIG. 3 illustrates a close up partial sectional view of the dicing blade 100 of FIG. 2 cutting through the semiconductor wafer 200. It can be seen that the leading edge 128 of the blade comprising first grit 125 will make first contact with the substance of the semiconductor wafer 200, thereby the first (coarser) grit will do a majority of the cutting of the kerf, and the second different and third (finer) grits 135, 145 will do the cutting in the vicinity of the finished die ground ring 210. Therefore, the smaller grit of the first and second surface regions 130, 140 will cause less peel off and chipping in the vicinity of the ground ring 210.

Note also that an increased grit concentration, i.e., number of grit pieces per volume, will also assist in reducing chipping. Additionally, the bonding material that holds the grit may be of varying hardness, i.e., soft, medium, or hard, and that the harder bond will result in more chipping, but less blade wear. Therefore, the exact natures of the first and second surface regions 130, 140, as well as the core 120, need to be optimized for these factors: grit size, grit concentration, region thickness, and bond hardness. The outer layer can have a smaller grit size as explained above, a higher grit concentration, and a soft to medium bond material to produce less chipping or peel off. By comparison, the core 120 should have a larger grit size, high concentration, and hard bond to resist wear.

FIG. 4 illustrates a profile view of the dicing blade 100 and a sectional view of the semiconductor wafer 200 along the center plane of the dicing blade 100 as it cuts. This further illustrates that the coarser, first grit 125 does the majority of the cutting, and with further reference to FIG. 3, it can be seen that the finer second different and third grits 135, 145 will finish the wall of the cut. A combination of table speed and spindle speed are parameters that should be controlled to produce maximum yields.

Thus, a dicing blade has been described for precision cutting of semiconductor wafers using a core material comprising a first grit in the core and a second different, finer grit in the surface regions of the dicing blade. In use, the coarser first grit does the majority of the cutting of the scribe street while avoiding the ground ring. The finer, second different grit performs the necessary cutting in the vicinity of the ground ring and therefore reduces the probability of peel off and chipping of the ground ring.

Those skilled in the art to which the invention relates will appreciate that other and further additions, deletions, substitutions and modifications may be made to the described embodiments without departing from the scope of the invention.

What is claimed is:

1. A semiconductor dicing blade, comprising:
a first region having a first grit therein; and
a second region coupled to said first region and having a second different grit therein, wherein a largest grit particle of said second different grit is smaller than a smallest grit particle of said first grit.

2. The semiconductor dicing blade as recited in claim 1 further comprising a third region coupled to said first region and having a third grit therein substantially equal in size to a size of said second different grit.

3. The semiconductor dicing blade as recited in claim 1 further comprising a matrix bonding said first grit and said second different grit.

4. The semiconductor dicing blade as recited in claim 3 wherein said matrix is a nickel matrix.

5. The semiconductor dicing blade as recited in claim 1 wherein a size of said first grit is less than about 10 microns.

6. The semiconductor dicing blade as recited in claim 1 wherein a size of said first grit ranges from about 4 microns to about 6 microns.

7. The semiconductor dicing blade as recited in claim 1 wherein a size of said second different grit is less than about 5 microns.

8. The semiconductor dicing blade as recited in claim 1 wherein a size of said second different grit ranges from about 2 microns to about 4 microns.

9. The semiconductor dicing blade as recited in claim 1 wherein a total thickness of said semiconductor dicing blade is about 20 microns.

10. A method of cutting a semiconductor wafer, comprising:
positioning a semiconductor dicing blade mounted in a wafer saw, wherein said semiconductor dicing blade comprises:
a core region having a first diameter and a first grit therein; and
a surface region coupled to said core region and having a second diameter, wherein said surface region has a second different grit therein, wherein said first diameter is slightly greater than said second diameter, and wherein a largest grit particle of said second different grit is smaller than a smallest grit particle of said first grit; and
operating said wafer saw to cut a semiconductor wafer with said semiconductor dicing blade.

11. The method as recited in claim 10 wherein operating includes operating wherein said first grit at a periphery of said core region cuts said semiconductor wafer before said second different grit at said surface region cuts said semiconductor wafer.

12. The method as recited in claim 10 wherein said positioning includes bonding said second different grit and said first grit in a matrix.

13. The method as recited in claim 12 wherein said bonding includes bonding in a nickel matrix.

14. The method as recited in claim 10 wherein a size of said first grit is less than about 10 microns, and wherein a size of said second different grit is less than about 5 microns.

15. The method as recited in claim 10 wherein a size of said first grit ranges from about 4 microns to about 6 microns.

16. The method as recited in claim 10 wherein a size of said second different grit ranges from about 2 microns to about 4 microns.

17. A semiconductor dicing blade, comprising:
a blade body;
a first grit located within a core of said blade body, said first grit having a first grit size and being exposed at a lead cutting edge of said blade body; and
a second different grit located on a side surface of said blade body, wherein a largest grit particle of said second different grit is smaller than a smallest grit particle of said first grit.

18. The semiconductor dicing blade as recited in claim 17 wherein a size of said first grit ranges from about 4 microns to about 6 microns, and wherein a size of said second different grit ranges from about 2 microns to about 4 microns.

19. The semiconductor dicing blade as recited in claim 17 wherein a total thickness of said semiconductor dicing blade is about 20 microns.

20. The semiconductor dicing blade as recited in claim 17 wherein said semiconductor dicing blade further comprises a metal matrix bonding said second different grit to said first grit.
